(19) United States
(12) Patent Application Publication
(10) Pub. No.: US 2026/0157045 A1
(43) Pub. Date: Jun. 4, 2026

(54) LIGHT EMITTING DISPLAY DEVICE AND METHOD OF DRIVING THE SAME

(71) Applicant: LG Display Co., Ltd., Seoul (KR)

(72) Inventors: Dong Cheol CHOE, Paju-si (KR); Sung Ji YOON, Paju-si (KR)

(73) Assignee: LG Display Co., Ltd., Seoul (KR)

(21) Appl. No.: 19/376,493

(22) Filed: Oct. 31, 2025

(30) Foreign Application Priority Data
Dec. 3, 2024 (KR) 10-2024-0177724

(51) Int. Cl. H10K 59/122; G09G 3/3225; H10K 50/15; H10K 59/38; H10K 59/80; H10K 102/00

(52) U.S. Cl. CPC H10K 59/122; G09G 3/3225; H10K 50/156; H10K 59/38; H10K 59/873; H10K 59/8792; H10K 2102/351

(57) ABSTRACT

A light emitting display device and a method of driving the same are discussed. The light emitting display device can include a bank provided on a substrate and exposing a red light emitting portion, a green light emitting portion, a blue light emitting portion, and a color-adjusting light emitting portion that are spaced apart from each other. The display device can further include a red light emitting device at the red light emitting portion, a green light emitting device at the green light emitting portion, a blue light emitting device at the blue light emitting portion, and a color-adjusting light emitting device provided in the color-adjusting light emitting portion. The display device further includes an encapsulation layer covering the red light emitting device, the green light emitting device, the blue light emitting device, and the color-adjusting light emitting device, and an anti-reflective layer on the encapsulation layer.

### CROSS-REFERENCE TO RELATED APPLICATIONS

This application claims priority to Korean Patent Application No. 10-2024-0177724, filed in the Republic of Korea on Dec. 3, 2024, which is hereby expressly incorporated by reference as if fully set forth herein.

### BACKGROUND OF THE INVENTION

### Field of the Invention

The present disclosure relates to a display device. More specifically, the present disclosure relates to a light emitting display device that maintains color balance although a viewing angle changes and has a color-specific lifespan balance in a structure including an anti-reflective layer instead of a polarizing plate, and a method of driving the same.

### Discussion of the Related Art

With the advent of the information society, there is increasing demand for various forms of display devices for displaying images.

A light emitting display device that includes light emitting devices to constitute pixels does not require a separate light source unit and is thus advantageous for slimness or flexibility and has excellent color purity.

For example, a light emitting device includes two different electrodes and a light emitting layer between the two different electrodes. When electrons generated from one electrode and holes generated from the other electrode are injected into the light emitting layer, the holes are combined with the electrons to form excitons, and the excitons fall from an excited state to a ground state, thereby resulting in light emission.

### SUMMARY OF THE INVENTION

Accordingly, the present disclosure is directed to a light emitting display device and a method of driving the same that substantially obviate one or more problems due to limitations and disadvantages of the related art.

One object of the present disclosure is to provide a light emitting display device that is capable of preventing or minimizing external light reflection without a polarizing plate that reduces light transmittance and of maintaining color balance.

Another object of the present disclosure is to provide a light emitting display device that is capable of adjusting lifespan characteristics of red, green, and blue colors to be similar to each other.

Another object of the present disclosure is to provide a light emitting display device that is capable of maintaining color-specific luminance balance when different colors are rendered.

Another object of the present disclosure is to provide a light emitting display device that is capable of preventing or minimizing the luminance of a specific color from being prominent although a viewing angle changes and thus achieving color-specific balance.

Additional advantages, objects, and features of the invention will be set forth in part in the description which follows and in part will become apparent to those having ordinary skill in the art upon examination of the following or can be learned from practice of the invention. The objectives and other advantages of the invention can be realized and attained by the structure particularly pointed out in the written description and claims hereof as well as the appended drawings.

To achieve these objects and other advantages and in accordance with the purpose of the invention, as embodied and broadly described herein, a light emitting display device includes a substrate, a bank provided on the substrate and exposing a red light emitting portion, a green light emitting portion, a blue light emitting portion, and a color-adjusting light emitting portion spaced apart from each other, a red light emitting device at the red light emitting portion, a green light emitting device at the green light emitting portion, a blue light emitting device at the blue light emitting portion, and a color-adjusting light emitting device provided in the color-adjusting light emitting portion, an encapsulation layer covering the red light emitting device, the green light emitting device, the blue light emitting device, and the color-adjusting light emitting device, and an anti-reflective layer on the encapsulation layer, the anti-reflective layer comprising a color filter overlapping the red light emitting portion, the green light emitting portion, the blue light emitting portion, and the color-adjusting light emitting portion.

In another aspect of the present disclosure, provided is a method of driving a light emitting display device including a red light emitting portion, a green light emitting portion, a blue light emitting portion, and a color-adjusting light emitting portion spaced apart from each other on a substrate, wherein the red light emitting portion is driven alone when red is driven, and the green light emitting portion is driven alone when green is driven, and the blue light emitting portion and the color-adjusting light emitting portion are driven together when blue is driven.

It is to be understood that both the foregoing general description and the following detailed description of the present disclosure are examples and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a plan view illustrating a light emitting display device according to one or more embodiments of the present disclosure;

FIG. 2 is a cross-sectional view illustrating a light emitting device corresponding to each light emitting portion of FIG. 1;

FIG. 3 is a cross-sectional view illustrating a light emitting display device taken along line I-I′ of FIG. 1;

FIG. 4 illustrates a pixel circuit of each subpixel of FIG. 3;

FIG. 5 illustrates color coordinates when a blue light emitting portion is driven alone and when a blue light emitting portion and a color-adjusting light emitting portion are driven simultaneously;

FIG. 6 is a graph showing the luminance depending on change in viewing angle when the red light emitting device and the blue light emitting device are driven;

FIG. 7 is a graph showing the luminance depending on change in viewing angle when the red light emitting device and the color-adjusting light emitting device are driven;

FIG. 8 is a graph showing the luminance depending on change in viewing angle when the blue light emitting device and the color-adjusting light emitting device are driven;

FIG. 9 illustrates an on/off state of light emitting portions in the light emitting display device of the present disclosure when blue is driven;

FIG. 10 illustrates the states in which the light emitting portions are turned on/off when red is driven in the light emitting display device of the present disclosure;

FIG. 11 shows the on/off states of the light emitting portions when the green is driven in the light emitting display device according to the disclosure; and

FIG. 12 is a plan view illustrating a light emitting display device according to another embodiment of the present disclosure.

### DETAILED DESCRIPTION OF THE EMBODIMENTS

Advantages and features of the present disclosure, and a method of achieving the advantages and features will become apparent with reference to the example embodiments described herein in detail together with the accompanying drawings. The present disclosure should not be construed as limited to the example embodiments as disclosed below, and can be embodied in various different forms. Thus, these example embodiments are set forth only to make the present disclosure sufficiently complete, and to assist those skilled in the art to fully understand the scope of the present disclosure. The protected scope of the present disclosure is defined by the claims and their equivalents.

In the following description of the present disclosure, where the detailed description of the relevant known steps, elements, functions, technologies, and configurations can unnecessarily obscure an important point of the present disclosure, a detailed description of such steps, elements, functions, technologies, and configurations may be omitted or may be provided briefly. In addition, the names of elements used in the following description are selected in consideration of clarity of description of the specification, and can differ from the names of elements of actual products. Furthermore, in the following detailed description of the present disclosure, numerous specific details are set forth in order to provide a sufficiently thorough understanding of the present disclosure. However, it will be understood that the present disclosure can be practiced without these specific details. In other instances, known methods, procedures, components, and circuits have not been described in detail so as not to unnecessarily obscure aspects of the present disclosure.

The shapes, sizes, ratios, angles, numbers, and the like, which are illustrated in the drawings to describe various example embodiments of the present disclosure are merely given by way of example. The disclosure is not limited to the illustrations in the drawings.

In the present specification, where terms such as “including,” “having,” “comprising,” and the like are used, one or more components can be added, unless the term, such as “only,” is used. As used herein, the term “and/or” includes a single associated listed item and any and all of the combinations of two or more of the associated listed items.

An expression such as “at least one of” when preceding a list of elements can modify the entire list of elements and may not modify the individual elements of the list. The term “at least one” should be understood as including any and all combinations of one or more of the associated listed items. For example, the meaning of “at least one of a first element, a second element, and a third element” encompasses the combination of all three listed elements, combinations of any two of the three elements, as well as each individual element, the first element, the second element, and the third element.

The terminology used herein is to describe particular aspects and is not intended to limit the present disclosure. As used herein, the terms “a” and “an” used to describe an element in the singular form is intended to include a plurality of elements. An element described in the singular form is intended to include a plurality of elements, and vice versa, unless the context clearly indicates otherwise.

In construing a component or numerical value, the component or the numerical value is to be construed as including an error or tolerance range even where no explicit description of such an error or tolerance range is provided.

In describing the various example embodiments of the present disclosure, where the positional relationship between two elements is described using terms, such as “on”, “above”, “under” and “next to”, at least one intervening element can be present between the two elements, unless “immediate(ly)” or “direct(ly)” or “close(ly) is used. It will be understood that when an element or layer is referred to as being “connected to”, or “coupled to” another element or layer, it can be directly connected to or coupled to the other element or layer, or one or more intervening elements or layers can be present.

In describing the various example embodiments of the present disclosure, when terms such as “after,” “subsequently,” “next,” and “before,” are used to describe the temporal relationship between two events, another event can occur therebetween, unless a more limiting term, such as “just,” “immediate(ly),” or “directly” is used.

In describing the various example embodiments of the present disclosure, terms such as “first” and “second” can be used to describe a variety of components. These terms aim to distinguish the same or similar components from one another and do not limit the components. Accordingly, throughout the specification, a “first” component can be the same as a “second” component within the technical concept of the present disclosure, unless specifically mentioned otherwise.

Features of various embodiments of the present disclosure can be partially or overall coupled to or combined with each other, and can be variously inter-operated with each other and driven technically as those skilled in the art can sufficiently understand. The embodiments of the present disclosure can be carried out independently from each other, or can be carried out together in a co-dependent relationship.

As used herein, the term “doped” layer refers to a layer including a first material and a second material (for example, n-type and p-type materials, or organic and inorganic substances) having physical properties different from the first material. Apart from the differences in properties, the first and second materials can also differ in terms of their amounts in the doped layer. For example, the host material can be a major component while the dopant material can be a minor component. The first material accounts for most of the weight of the doped layer. The second material can be added in an amount less than 30% by weight, based on a total weight of the first material in the doped layer. A “doped” layer can be a layer that is used to distinguish a host material from a dopant material of a certain layer, in consideration of the weight ratio. For example, if all of the materials constituting a certain layer are organic materials, at least one of the materials constituting the layer is n-type and the other is p-type, when the n-type material is present in an amount of less than 30 wt %, or when the p-type material is present in an amount of less than 30 wt %, the layer is considered to be a “doped” layer.

Further, the term “undoped” refers to layers that are not “doped”. For example, a layer can be an “undoped” layer when the layer contains a single material or a mixture including materials having the same properties as each other. For example, if at least one of the materials constituting a certain layer is p-type and none of the materials constituting the layer are n-type, the layer is considered to be an “undoped” layer. For example, if at least one of the materials constituting a layer is an organic material and none of the materials constituting the layer are inorganic materials, the layer is considered to be an “undoped” layer.

In this present disclosure, an electroluminescence (EL) spectrum can be calculated by multiplying (a) a photoluminescence (PL) spectrum, which applies the inherent characteristics of an emissive material such as a dopant material or a host material included in an organic emission layer, by (b) an outcoupling or emittance spectrum curve, which is determined by the structure and optical characteristics of an organic light-emitting element including the thicknesses of organic layers such as, for example, an electron transport layer.

Hereinafter, example embodiments of the present disclosure will be described in detail with reference to the accompanying drawings. In adding reference numerals to elements of each of the drawings, although the same elements are illustrated in other drawings, like reference numerals can refer to like elements.

Hereinafter, the light emitting display device according to the present disclosure will be described with reference to the attached drawings.

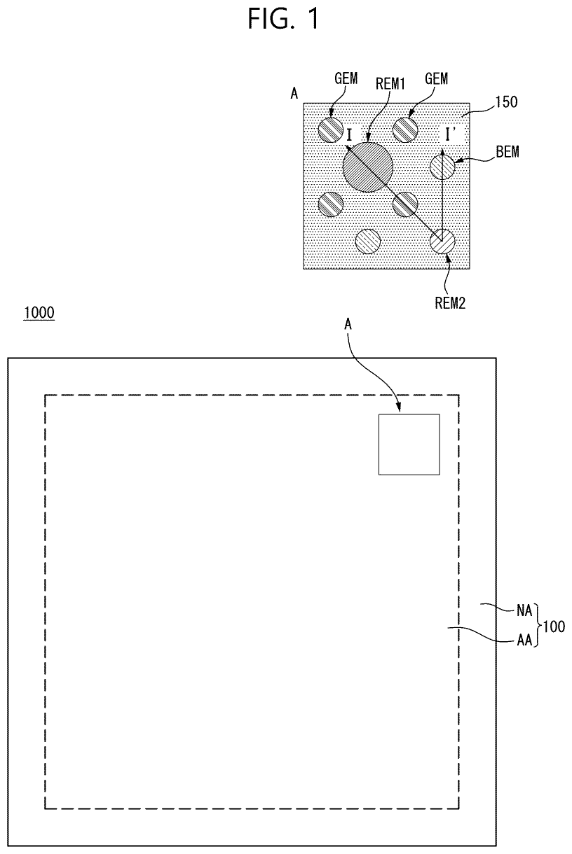

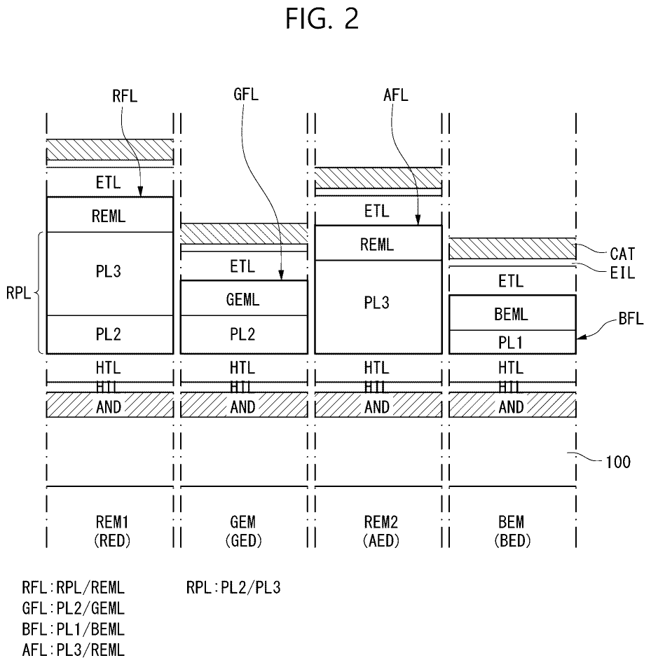

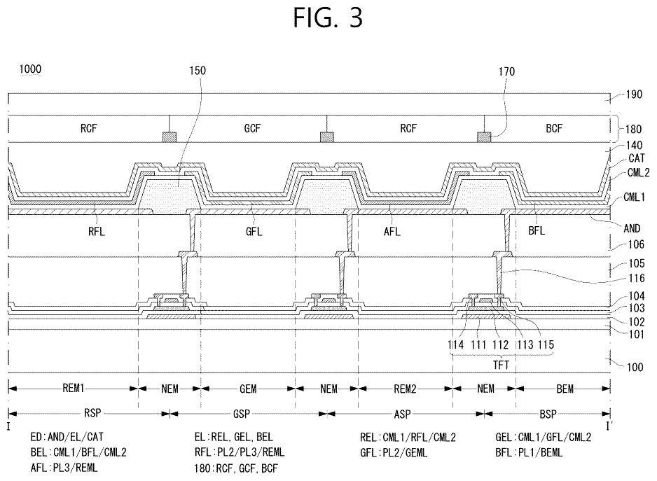

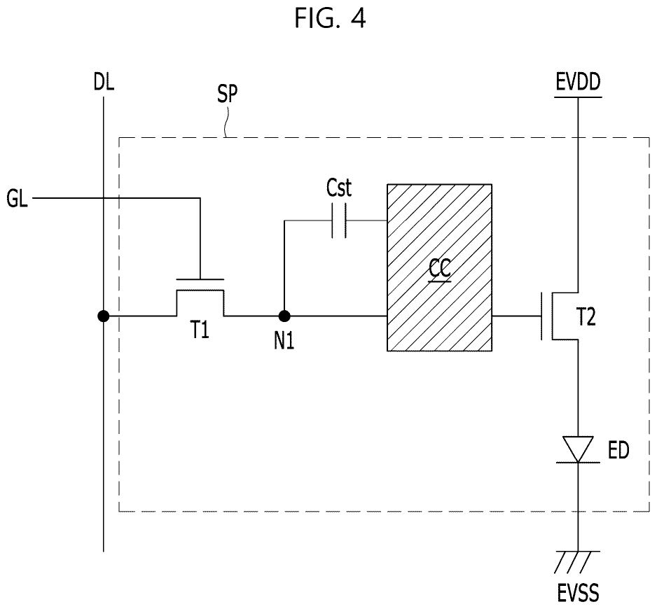

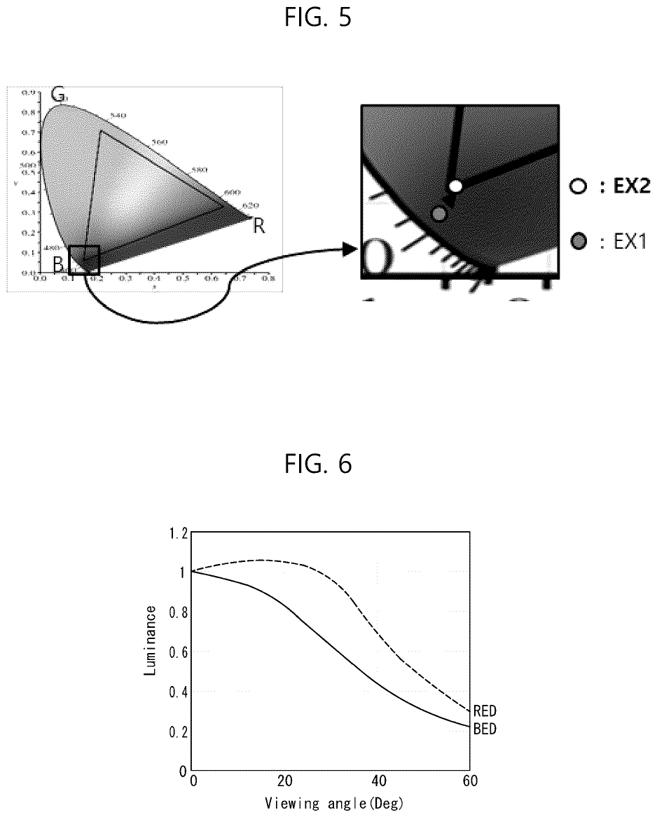

FIG. 1 is a schematic diagram illustrating a light emitting display device according to one or more embodiments of the present disclosure. FIG. 2 is a cross-sectional view illustrating a light emitting device corresponding to each light emitting portion of FIG. 1. FIG. 3 is a cross-sectional view illustrating a light emitting display device taken along line I-I′ of FIG. 1. FIG. 4 illustrates a pixel circuit of each subpixel of FIG. 3. FIG. 5 illustrates color coordinates when a blue light emitting portion is driven alone and when a blue light emitting portion and a color-adjusting light emitting portion are driven simultaneously.

As shown in FIG. 1, a light emitting display device 1000 according to an embodiment of the present disclosure includes a substrate 100 divided into a display area (or active area) AA and a non-display area (or non-active area) NA.

The display area AA of the substrate 100 includes a plurality of subpixels SP to display an image. The plurality of subpixels SP may comprise a red subpixel RSP, a green sub pixel GSP and a blue subpixel BSP with a color-adjusting subpixel ASP. The non-display area NA is disposed around the display area AA, and a driving unit and a bezel can be disposed. The non-display area NA can include pad electrodes that receive signals from the driving unit at the outermost extended portions of the gate lines GL and data lines DL disposed in the display area AA. The pad electrodes can be connected to the driving unit.

Here, the display area AA is referred to as an active area and the non-display area NA is also referred to as a non-active area.

The display area AA includes a plurality of subpixels SP, as shown in FIGS. 1 to 4.

The substrate 100 can include a plurality of gate lines GL and a plurality of data lines DL, and can include a subpixel SP disposed at each of the intersections of a plurality of gate lines GL and a plurality of data lines DL. The structure of the subpixel SP can vary depending on the type of the light emitting display device 1000.

In the non-display area NA, the driving unit can include, for example, a scan driver that supplies a scan signal to drive a gate line GL provided in the display area AA, and a data driver that transmits a data signal to the data line DL. In addition, the driving unit can include an image processor, a timing controller, and a power supply to control the generation and supply of the scan signal and the data signal. The image processor, the timing controller, and the power supply can be disposed on a separate circuit board and connected to the substrate 100.

The display area AA displays an image in response to a data signal supplied from the data driver, a scan signal supplied from the scan driver, and power supplied from the power supply.

For example, the subpixels SP can be formed in a top emission method, a bottom emission method, or a dual emission method depending on the structure. The subpixels SP are units that can emit light of their own color with or without a specific type of color filter. For example, the subpixels SP can include a red subpixel, a green subpixel, and a blue subpixel. Alternatively, the subpixel SP can include, for example, a white subpixel in addition to the red subpixel, the green subpixel and the blue subpixel.

Each subpixel SP: RSP, GSP, BSP and ASP can include a light emitting portion REM1, GEM, BEM and REM2 where light is emitted, and a non-light emitting portion NEM surrounding the light emitting portion and overlapping the bank 150. For an example, referring FIG. 1, the non-light emitting portion NEM outside of the light emitting portions REM1, GEM, BEM and REM2 may be integral and connected each other between adjacent subpixels. A bank 150 may be disposed at the non-light emitting portion NEM. The subpixels SP can have areas of one or more different light emitting portions depending on light emitting characteristics.

The light emitting portions REM1, GEM, and BEM that emit different colors can be distinguished, for example, by different color light emitting layers included at the respective areas.

The red light emitting portion REM1 emits red light, the green light emitting portion GEM emits green light, and the blue light emitting portion BEM emits blue light.

Each red light emitting portion REM1 includes a red light emitting layer REML, the green light emitting portion GEM includes a green light emitting layer GEML, and the blue light emitting portion BEM includes a blue light emitting layer BEML.

For example, as shown in FIG. 1, the red light emitting portion REM1 can have a larger area than the blue light emitting portion BEM or the green light emitting portion GEM. When one light emitting portion has a larger area, the reflection visibility for external light can be improved from one light emitting portion with a larger area than the other light emitting portion with a smaller area. For example, when the red light emitting portion REM1 is designed to be larger, the perception of color complementary to red can be corrected in the initial state. For example, when the red light emitting portion REM1 has a similar size to the blue light emitting portion BEM or the green light emitting portion GEM, cyan can appear in the initial state. However, the size of the red light emitting portion REM1 is increased to improve the reflection luminance of red in the initial state, so that normal black having no color deviation can be obtained.

Meanwhile, the light emitting display device according to the embodiment of the present disclosure further includes a color-adjusting light emitting portion REM2 in addition to the red, green and blue light emitting portions REM1, GEM, and BEM.

The size of the color-adjusting light emitting portion REM2 can be smaller than or the same as the size of the red light emitting portion REM1.

The red light emitting portion REM1 includes a red light emitting device RED, the green light emitting portion GEM includes a green light emitting device GED, and the blue light emitting portion BEM includes a blue light emitting device BEM.

The color-adjusting light emitting portion REM2 includes a red light emitting layer REML, but has a different optical distance from the red light emitting portion REM1. The color-adjusting light emitting portion REM2 includes a color-adjusting light emitting device AED, is disposed in the display area AA, and is turned on when the blue light emitting device BED of the blue light emitting portion BEM is turned on, and corrects the color coordinate of blue.

The color-adjusting light emitting portion REM2 can have a different area from the red light emitting portion REM1. For example, the color-adjusting light emitting portion REM2 can have the same size as the blue light emitting portion BEM that is driven together.

The color-adjusting light emitting portion REM2 functions not to emit light, but to correct the color of the blue light emitting portion BEM. When a blue light emitting portion BEM is singly driven according to the first experimental Example EX1, a color coordinate is biased toward deep blue color, as shown in FIG. 5. On the contrary, when the color-adjusting light emitting device AED is driven along with the blue light emitting device BED according to the second experimental Example EX2, as shown in FIG. 5, a color coordinate is shifted to the upper right diagonal direction, which is the direction of red, so that light adjusted to pure blue is finally emitted. A left drawing of FIG. 5 shows an entire color coordinates representing all areas of red (R), green (G) and blue (B). And a right drawing of FIG. 5 shows an enlarged selection area of the blue (B) area in the left drawing. The right drawing of FIG. 5 shows the color coordinates of blue color (B) according to the first and second experimental Examples EX1 and EX2.

When the blue light emitting device BED is driven along with the color-adjusting light emitting device AED (EX2), the blue light emission peak can be shifted in the longer wavelength direction by 1 nm to 10 nm compared to when the blue light emitting device BED is driven alone (EX1), thereby providing emission of long-wavelength light. For example, when the blue light emitting device BED driven alone has an EL peak of 440 nm to 480 nm, the color-adjusting light emitting device AED can be driven along therewith to adjust an EL peak in the range of 441 nm to 490 nm, which is shifted in the longer wavelength direction.

In recent light emitting display devices, the blue light emitting layer BEML in the blue light emitting portion BEM includes a deep blue dopant to improve efficiency. Accordingly, when the blue light emitting portion BEM is driven alone, the CIE color coordinates are excessively biased toward deep blue and thus there is a limitation in color expression. However, the light emitting display device according to the embodiment of the present disclosure can expand color expression by driving the color-adjusting light emitting portion in order to correct the color coordinates.

The arrangement density of the color-adjusting light emitting portion REM2 on the substrate 100 can be lower than the arrangement density of the red light emitting portion REM1.

The color-adjusting light emitting portion REM2 is provided to correct blue and does not reduce the red light emission efficiency of the red light emitting portion REM1.

The arrangement density of the color-adjusting light emitting portion REM2 on the substrate 100 can be lower than the arrangement density of the blue light emitting portion BEM. When the blue light emitting portion BEM is driven, the color-adjusting light emitting portion REM2 is driven along therewith, and the color-adjusting light emitting portion REM2 is provided to correct blue, functions to compensate for driving of the blue light emitting portion BEM, and can emit light with a lower luminance than blue luminance.

In some cases, the arrangement density of the color-adjusting light emitting portion REM2 can be greater than that of the blue light emitting portion BEM, so that the color coordinates can be corrected greatly when blue is corrected.

The bank 150 exposes the light emitting portion REM1, GEM, BEM, REM2 of each subpixel SP: RSP, GSP, BSP, ASP and is disposed to overlap with the non-light emitting portion NEM.

Specifically, the red light emitting device RED of the red light emitting portion REM1 will be described with reference to FIG. 2.

The red light emitting device RED includes a first electrode AND and a second electrode CAT which face each other, and includes a hole transport common layer including a hole injection layer and a hole transport layer, a red hole transport auxiliary layer RPL, a red light emitting layer REML, an electron transport layer ETL, and an electron injection layer EIL between the first electrode AND and the second electrode CAT.

The first electrode AND can be an anode and the second electrode CAT can be a cathode.

The first electrode AND can include, for example, a metal material having high reflectivity or a transparent electrode. For example, the first electrode AND can be formed of a single layer structure of a transparent conductive layer such as ITO (indium tin oxide), IZO (indium zinc oxide), TO (tin oxide), or ITZO (indium tin zinc oxide), a multilayer structure such as a stacked structure of aluminum (Al) and titanium (Ti) (Ti/Al/Ti), a stacked structure of aluminum (Al) and ITO (ITO/Al/ITO), an APC (Ag/Pd/Cu) alloy, a stacked structure of an APC alloy and ITO (ITO/APC/ITO), a stacked structure of silver (Ag) and molybdenum/titanium alloy (Ag/MoTi), or can include a single layer structure formed of one material selected from silver (Ag), aluminum (Al), molybdenum (Mo), gold (Au), magnesium (Mg), calcium (Ca), and barium (Ba), or an alloy of two or more thereof. When the first electrode AND is formed of a single layer of a transparent conductive layer, light from the light emitting device ED can be emitted through the first electrode AND. When the first electrode AND includes a reflective electrode, light can be emitted through the second electrode CAT facing the first electrode AND.

In the light emitting display device 1000 according to the embodiment of the present disclosure, the second electrode CAT can include a transparent electrode or a thin reflective-transparent electrode that can transmit light so that light can be transmitted through the second electrode CAT. The transparent electrode can be, for example, ITO or IZO, and the reflective-transparent electrode can be formed of, for example, one material selected from silver (Ag), aluminum (Al), molybdenum (Mo), gold (Au), magnesium (Mg), ytterbium (Yb), and strontium (Sr), or an alloy material of two or more.

The second electrode CAT can include a transmissive electrode. For example, the second electrode CAT can include a transparent metal material (TCO, transparent conductive material) such as ITO (indium tin oxide), IZO (indium zinc oxide) that can transmit light, or a semi-transmissive metal material such as magnesium (Mg), silver (Ag), or an alloy of magnesium (Mg) and silver (Ag). When the second electrode CAT includes a semi-transparent metal material, the light emission efficiency can be increased by the microcavity effect. When the second electrode CAT includes a semi-transparent metal material, the thickness thereof is thin enough to allow light to pass therethrough.

The hole injection layer HIL directly contacts the first electrode AND, which is a metal of a reflective electrode or a transparent electrode component, and has the function to lower the energy barrier at the interface with the first electrode AND. The hole injection layer HIL can include an inorganic material of metal fluoride to lower the energy barrier at the interface with the first electrode AND. Alternatively, the hole injection layer HIL can include a p-type dopant in the hole transport organic material.

The hole transport layer HTL can include a hole transport material. For example, the hole transport material can include at least one of NPD (N,N-dinaphthyl-N,N′-diphenylbenzidine), TPD (N,N′-bis-(3-methylphenyl)-N,N′-bis-(phenyl)-benzidine), spiro-TAD (2,2′7,7′-tetrakis(N,N-diphenylamino)-9,9-spirobifluorene) or MTDATA (4,4′,4″-tris(N-3-methylphenyl-N-phenyl-amino)-triphenylamine), but is not limited thereto.

The red hole transport auxiliary layer RPL can include a hole transport material. The red light emitting portion REM1 emits light with an emission peak of 600 nm to 650 nm and adjusts the vertical position of the red light emitting layer REM1 so that red light emitted from the red light emitting layer REML optimally resonates between the first and second electrodes AND and CAT. The thickness of the red hole transport auxiliary layer RPL can be greater than that of the hole transport auxiliary layer of the green light emitting portion GEM or the blue light emitting portion BEM that emits light with relatively short wavelengths.

The red light emitting layer REML includes a red dopant having an emission peak at a wavelength of 600 nm to 650 nm and a host that helps excitation of the dopant, and can emit red light. The red dopant of the red light emitting layer REML can include an iridium-based phosphorescent dopant to provide predetermined luminance characteristics. The red dopant can adjust the emission wavelength to a long wavelength by changing the substituent.

The red hole transport auxiliary layer RPL and the red light emitting layer REML form a red optional layer RFL having a laminated configuration provided at least in the red light emitting portion REM1.

The electron transport common layer CML2 can include a hole blocking layer HBL, an electron transport layer ETL, and an electron injection layer EIL.

The hole blocking layer HBL is located on the opposite side of the electron blocking layer EBL with the light emitting layer REML, GEML and BEML therebetween, and functions to confine holes so that they do not escape from the light emitting layer REML, GEML and BEML and contribute to excitation.

The electron injection layer EIL has the function of reducing the energy barrier when electrons are injected into the organic material from the second electrode CAT. The electron injection layer EIL can have a smaller thickness compared to the hole transport layer ETL and can include a metal such as an alkali metal, an alkaline earth metal, a transition metal, or a halogen material.

The electron transport layer ETL has the function of transferring electrons injected from the second electrode CAT into the electron injection layer EIL to the light emitting layer REML, GEML and BEML. The electron transport layer ETL can be formed of one or more selected from the group consisting of, for example, Alq3 (tris(8-hydroxyquinolino aluminum), PBD, TAZ, spiro-PBD, BAlq, Liq (lithium quinolate), BMB-3T, PF-6P, TPBI, COT, and SAlq, but the present disclosure is not limited thereto.

Hereinafter, the green light emitting device GED provided in the green light emitting portion GEM and the blue light emitting device BED provided in the blue light emitting portion BEM will be described compared to the red light emitting device RED.

The green light emitting device GED and the blue light emitting device BED have the same configuration as the red light emitting device RED except that the green optional layer GFL in the green light emitting device GED, and the blue optional layer BFL in the blue light emitting device BED are each different from the red optional layer RFL of the red light emitting device RED. However, the first electrode AND is formed separately in each subpixel RSP, GSP, or BSP. In this case, the first electrode AND is provided at least in the light emitting portion of each subpixel RSP, GSP, or BSP, but the edge thereof overlaps a part of the bank 150, and the first electrodes AND on the adjacent light emitting portions can be spaced apart from each other in the area of the bank 150 between the adjacent light emitting portions. The hole injection layer HIL, the hole transport layer HTL, the electron transport layer ETL, the electron injection layer EIL, and the second electrode CAT can be provided continuously without interruption in a plurality of subpixels RSP, GSP, and BSP.

Meanwhile, the blue light emitting device BED is provided with a first hole transport auxiliary layer PL1 that adjusts the vertical phase of the blue light emitting layer BEML to adjust the optical distance between the first and second electrodes AND and CAT. The green light emitting device GED is provided with a second hole transport auxiliary layer PL2 that adjusts the vertical phase of the green light emitting layer GEML to adjust the optical distance between the first and second electrodes AND and CAT. As shown in FIG. 2, the second hole transport auxiliary layer PL2 of the green light emitting portion GEM can be thicker than the first hole transport auxiliary layer PL1 of the blue light emitting portion BEM. The first and second hole transport auxiliary layers PL1 and PL2 are each disposed between the hole transport layer HTL and each light emitting layer BEML or GEML.

The blue light emitting layer BEML includes a blue dopant and a blue host having an emission peak at a wavelength of 430 nm to 480 nm. The blue dopant of the blue light emitting layer BEML can include a boron-based fluorescent dopant to improve efficiency and provide a predetermined lifetime or longer.

The green light emitting layer GEML includes a green dopant and a green host having an emission peak at a wavelength of 500 nm to 595 nm. The green light emitting layer GEML can emit green light. The green dopant of the green light emitting layer GEML can include an iridium-based phosphorescent dopant for luminance characteristics having a predetermined efficiency or higher.

The color-adjusting light emitting portion REM2 can include a third hole transport auxiliary layer PL3 thicker than the second hole transport auxiliary layer PL2 of the green light emitting portion GEM. This aims at adjusting the optical distance required for the resonance of the red light emitting layer REML included in the color-adjusting light emitting portion REM2.

The red light emitting layer REML included in the color-adjusting light emitting portion REM2 can be the same material and thickness as the red light emitting layer REML included in the red light emitting portion REM1. In this case, the red light emitting layer REML included in the color-adjusting light emitting portion REM2 can be formed using the same deposition process as in the red light emitting layer REML included in the red light emitting portion REML1, thereby reducing materials and simplifying the process.

Alternately, the red light emitting layer REML included in the color-adjusting light emitting portion REM2 can have a different red host and/or red dopant or a different thickness from the red light emitting layer REML included in the red light emitting portion REM1. The color-adjusting light emitting portion REM2 is not provided for clear red light emission, but is provided for weak luminance when the blue light emitting portion BEM is driven to compensate for the color coordinates of blue. For this purpose, the driving voltage for driving the blue light emitting device BED of the blue light emitting portion BEM can be greater than the driving voltage for driving the color-adjusting light emitting device AED of the color-adjusting light emitting portion REM2.

The thicknesses of the first hole transport auxiliary layer PL1, the second hole transport auxiliary layer PL2, and the red hole transport auxiliary layer RPL are related to the wavelength of color of light emitted from each light emitting portion BEM, GEM, or REM1. For example, the thickness of the first hole transport auxiliary layer PL1 is approximately 3 nm to 8 nm, the thickness of the second hole transport auxiliary layer PL2 is approximately 7 nm to 15 nm, and the thickness of the red hole transport auxiliary layer RPL is approximately 65 nm to 75 nm.

Meanwhile, the thickness of the third hole transport auxiliary layer PL3 provided in the color-adjusting light emitting portion REM2 is approximately 50 nm to 68 nm, which corresponds to the thickness obtained by subtracting the thickness of the second hole transport auxiliary layer PL2 from the thickness of the red hole transport auxiliary layer RPL. The thickness of the red hole transport auxiliary layer RPL can be larger than the thickness of the third hole transport auxiliary layer PL3. (PL3=RPL−PL2)

The first to third hole transport auxiliary layers PL1, PL2, and PL3 can be identical or different hole transport materials. In any case, the first to third hole transport auxiliary layers PL1, PL2, and PL3 are disposed between the hole transport layer HTL and each color light emitting layer BEML, GEML, or REML, and can be selected from hole transport materials that do not impede the flow of holes when each light emitting portion is driven.

Meanwhile, the light emitting display device according to the embodiment of the present disclosure further includes a color-adjusting light emitting portion REM2 in addition to the red, green and blue light emitting portions REM1, GEM, and BEM on the substrate 100. In order not to provide a separate additional mask for forming the color-adjusting light emitting portion REM2, the third hole transport auxiliary layer PL3, which is a component of the auxiliary optional layer AFL of the color-adjusting light emitting portion REM2, is also provided in the red light emitting portion REM1 when the third hole transport auxiliary layer PL3 is formed. In addition, in order to satisfy the resonance thickness required for the red hole transport auxiliary layer RPL included in the red light emitting portion REM1, the second hole transport auxiliary layer PL2 can be also formed in the red light emitting portion REM1 when the second hole transport auxiliary layer PL2 of the green light emitting portion GEM is formed. Therefore, the red hole transport auxiliary layer RPL can be provided by laminating the second hole transport auxiliary layer PL2 and the third hole transport auxiliary layer PL3.

Regarding the thickness of the first to third hole transport auxiliary layers PL1, PL2, and PL3, the thickness increases from the first hole transport auxiliary layer PL1 toward the third hole transport auxiliary layer PL3.

The thickness of the third hole transport auxiliary layer PL3 is greater than the total thickness of the first and second hole transport auxiliary layers PL1 and PL2.

The color-adjusting light emitting device AED disposed on the color-adjusting light emitting portion REM2 includes a first electrode AND and a second electrode CAT facing each other on a substrate 100, and includes a configuration of a hole injection layer HIL, a hole transport layer HTL of a hole transport common layer CML1, an auxiliary optional layer AFL, an electron transport layer ETL, and an electron injection layer EIL between the first electrode AND and the second electrode CAT. Here, the auxiliary optional layer AFL has a laminated configuration of a third hole transport auxiliary layer PL3 and a red light emitting layer REML. In addition, the color-adjusting light emitting device AED can include the same red light emitting layer REML as the red light emitting device RED, and an optical distance between the first and second electrodes AND and CAT of the color-adjusting light emitting device AED can be shorter than an optical distance between the first and second electrodes AND and CAT of the red light emitting device RED.

The first to third hole transport auxiliary layers PL1, PL2, and PL3 can be selected from hole transport materials.

The first to third hole transport auxiliary layers PL1, PL2, and PL3 can be formed of an identical material.

At least one of the first to third hole transport auxiliary layers PL1, PL2, and PL3 can be a different material from the others.

In another embodiment, the blue light emitting portion BEM, the green light emitting portion GEM, the red light emitting portion REM1, and the color-adjusting light emitting portion REM2 commonly have a first hole transport auxiliary layer PL1 having the same thickness, the green light emitting portion GEM further includes a hole transport auxiliary layer having a thickness equal to the thickness obtained by subtracting the thickness of the first hole transport auxiliary layer PL1 from the thickness of the second hole transport auxiliary layer PL2, the color-adjusting light emitting portion REM2 further includes a hole transport auxiliary layer with a thickness equal to the thickness obtained by subtracting the thickness of the first hole transport auxiliary layer PL1 from the thickness of the third hole transport auxiliary layer PL3, and the red light emitting portion REM1 further includes a hole transport auxiliary layer having a thickness equal to the thickness obtained by subtracting the thickness of the first hole transport auxiliary layer PL1 from the thickness of the red hole transport auxiliary layer RPL, so that each light emitting portion functions as an optical compensation layer depending on the optimal resonance. In this case, the first hole transport auxiliary layer PL1 commonly provided in the blue light emitting portion BEM, the green light emitting portion GEM, the red light emitting portion REM1, and the color-adjusting light emitting portion REM2 can be an electron blocking layer. The electron blocking layer functions to prevent electrons from escaping from each light emitting layer toward the hole transport layer HTL and can include a material having a higher LUMO energy level than each light emitting layer. The electron blocking layer can include a material having a wider energy band gap than the adjacent hole transport auxiliary layer or hole transport layer.

In the light emitting display device according to the embodiment of the present disclosure, the color-adjusting light emitting portion REM2 and the red light emitting portion REM1 emit red light, but the optical distances between the first electrode AND and the second electrode CAT (e.g., the cathode)are different and thus the outcoupling emittance spectra are different. Accordingly, the EL spectra of the color-adjusting light emitting portion REM2 and the red light emitting portion REM1 can be different. The intensity of the EL spectrum of the red light emitting portion REM1 can be greater than that of the color-adjusting light emitting portion REM2. The peak of the EL spectrum of the color-adjusting light emitting portion REM2 can be shorter than that of the EL spectrum of the red light emitting portion REM1.

The color-adjusting light emitting portion REM2 and the red light emitting portion REM1 each include a red light emitting layer REML, so that the difference in EL spectra peaks between the color-adjusting light emitting portion REM2 and the red light emitting portion REM1 can be 10 nm or less.

Hereinafter, the configuration connected to the light emitting devices RED, GED, BED and AED) in the light emitting display device according to the embodiment of the present disclosure will be described with reference to FIGS. 3 and 4.

As shown in FIG. 4, each subpixel SP: RSP, GSP, BSP, ASP within the display area AA can include, for example, a first transistor T1, a second transistor T2, a storage capacitor Cst, a compensation circuit CC, and a light emitting device ED.

For example, the first transistor T1 can be a switching transistor and the second transistor T2 can be a driving transistor.

Referring FIG. 4, a first source-drain electrode of the first transistor T1 is electrically connected to the data line DL, and a second electrode is electrically connected to the first node N1. A gate electrode of the first transistor T1 is electrically connected to the gate line GL. The first transistor T1 transmits the data signal supplied through the data line DL to the first node N1 in response to the scan signal supplied through the gate line GL.

The storage capacitor Cst is electrically connected to the first node N1 and charges the voltage applied to the first node N1.

A first source-drain electrode of the second transistor T2 may receive a high potential driving voltage EVDD and a second source-drain electrode of the second transistor T2 can be electrically connected to the first electrode AND as shown in FIG. 3. The second transistor T2 can control the amount of driving current flowing through the light emitting device ED: RED, GED, AED, and BED in response to the voltage applied to the gate electrode.

The semiconductor layer of the first transistor T1 and/or the second transistor T2 can contain silicon such as amorphous silicon (a-Si), polycrystalline silicon (poly-Si), or low-temperature polycrystalline silicon (poly-Si), or can contain an oxide such as IGZO (indium-gallium-zinc-oxide), but is not limited thereto. At least one of the first and second transistors T1 and T2 can include an oxide semiconductor layer, can be formed at a relatively low temperature compared to other materials, can maintain amorphous characteristics and can have high mobility.

The light emitting device ED emits light corresponding to the driving current. The light emitting device ED can emit red, green, blue or white light. The second transistor T2 may supply the driving current to the light emitting device ED.

The light emitting device ED can include a first electrode AND, an intermediate layer EL disposed on the first electrode AND, and a second electrode CAT. The second electrode CAT may be connected a voltage line supplying a low potential voltage EVSS. The low potential voltage EVSS may be a ground voltage or a constant voltage lower than a threshold voltage of the light emitting device ED. The low potential voltage EVSS may be applied to the second electrode CAT of each subpixel as a common voltage. The second electrode CAT may be positioned over the plurality of subpixels SP: RSP, GSP, ASP and BSP. As shown in FIG. 2, the intermediate layer EL can include a hole transport common layer CML1, a color optional layer RFL, GFL, BFL or AFL, and an electron transport common layer CML2 and emit light of color through the corresponding color optional layer RFL, GFL, BFL, or AFL at each subpixel.

The compensation circuit CC can be provided in the subpixel SP to compensate for the threshold voltage of the second transistor T2. The compensation circuit CC can include one or more transistors. The compensation circuit CC can include at least one transistor and capacitor, and can be configured in various configurations depending on the compensation method. The pixel including the compensation circuit CC can have various circuits with a variety of structures including transistors such as 3T1C, 4T2C, 5T2C, 6T1C, 6T2C, 7T1C, and 7T2C, or various numbers of transistors.

Meanwhile, the pixel circuit of the subpixel shown in FIG. 4 can be provided for each subpixel. The thin film transistor TFT shown in FIG. 3 can be, for example, the second transistor T2 of FIG. 4.

In another embodiment of the present disclosure, the color-adjusting light emitting portion REM2 and the blue light emitting portion BEM can share or connect the first electrode AND to drive the color-adjusting light emitting portion REM2 and the blue light emitting portion BEM simultaneously.

The substrate 100 on which each subpixel RSP, GSP, BSP, or ASP is disposed can be formed as a single layer or a plurality of layers. An area including a red light emitting portion REM1 and an adjacent non-light emitting portion NEM can correspond to a red subpixel RSP, an area including a green light emitting portion GEM and an adjacent non-light emitting portion NEM can correspond to a green subpixel GSP, and an area including a blue light emitting portion BEM and an adjacent non-light emitting portion NEM can correspond to a blue subpixel BSP. Here, an area including a color-adjusting light emitting portion REM2 and an adjacent non-light emitting portion NEM is referred to as a “color-adjusting subpixel” ASP. The color-adjusting subpixel ASP can be driven along with the blue subpixel BSP.

The substrate 100 can include at least one of a glass substrate, a plastic film, or a metal plate having a predetermined supporting force. The substrate 100 can be formed of a flexible material. For example, when the substrate 100 is formed of multiple layers, it can have a stacked structure of a first organic film, an inorganic insulating layer, and a second organic film. The first organic film on the outermost side can prevent the introduction of external impurities and have a protective function. The second organic film can function to planarize the formation surface of the internal array structure and to prevent charge transfer or impurity transfer from the outside to the inside. The inorganic insulating layer between the first and second organic films can function to prevent diffusion of moisture and impurities between the first and second organic films.

A first insulating layer 101 can be provided on the substrate 100. The first insulating layer 101 can function as a buffer layer or an active buffer layer. The buffer layer and the active buffer layer can function to prevent impurities from being transferred from the lower side of the wiring and active layer included in the internal array to the upper side and to support and protect the upper components. The first insulating layer 101 can have multiple layers.

A thin film transistor TFT and a storage capacitor can be disposed on the first insulating layer 101 in each subpixel RSP, GSP, BSP or ASP.

A light blocking layer 111 can be provided on the first insulating layer 101 to prevent light from being transmitted from below to the active layer 112 of the thin film transistor TFT.

A second insulating layer 102 can be disposed between the light blocking layer 111 and the active layer 112 for insulation.

The thin film transistor TFT can be disposed on each of a plurality of subpixels on the second insulating layer 102. For example, the thin film transistor TFT can include an active layer 112, a gate electrode 113 overlapping the active layer 112 with a third insulating layer 103 interposed therebetween, and a first source-drain electrode 114 and a second source-drain electrode 115 connected to both sides of the active layer 112.

For example, a storage capacitor can include a first storage electrode and a second storage electrode overlapping each other. At least one of the first and second storage electrodes can be formed of the same material as the active layer 112, and the other can include the same material as the gate electrode 113, the first and second source-drain electrodes 114 and 115, and the light blocking layer 111.

The third insulating layer 103 between the active layer 112 and the gate electrode 113 can function as a gate insulating layer.

The active layer 112 can include, for example, a silicon-based or oxide semiconductor. The silicon-based semiconductor can include crystalline and/or amorphous silicon. The oxide semiconductor can include at least one of gallium oxide, tin oxide, zinc oxide, indium oxide, iron oxide, or indium-gallium-zinc oxide. The oxide semiconductor layer can be formed of multiple layers having different materials or different material composition ratios. Each subpixel can include multiple thin film transistors and the thin film transistors can be disposed on different layers. For example, each subpixel of the substrate 100 can include a plurality of thin film transistors having different active layers. For example, the first thin film transistor can be formed as a silicon-based active layer and can be closer to the substrate 100, and the second thin film transistor can be formed as an oxide semiconductor active layer above the first thin film transistor.

The active layer 112 can include a channel region overlapping the gate electrode 113 and a source/drain region connected to each of the first and second source/drain electrodes 114 and 115.

The third insulating layer 103 can be selectively disposed corresponding to the channel region of the active layer 112 and can be provided over the entire surface of the substrate 100 excluding the region through which the first and second source-drain electrodes 114 and 115 penetrate. The third insulating layer 103 can function to insulate the active layer 112 from the gate electrode 113. The third insulating layer 103 can be formed of an inorganic insulating material and can be formed as, for example, a silicon oxide layer (SiOx), a silicon nitride layer (SiNx), a silicon oxynitride layer (SiOxNy), or a multilayer layer thereof.

A gate electrode 113 can be formed on the third insulating layer 103. The gate electrode 113 can be disposed to face the active layer 112 with the third insulating layer 103 interposed therebetween.

A fourth insulating layer 104 can be formed on the gate electrode 113 to cover and protect the gate electrode 113. In addition, the fourth insulating layer 104 can function to protect at least one electrode of the thin film transistor TFT and the active layer 112. The fourth insulating layer 104 can be formed of an inorganic insulating material. For example, the fourth insulating layer 104 can be formed as a silicon oxide layer (SiOx), a silicon nitride layer (SiNx), a silicon oxynitride layer (SiOxNy), or a multilayer layer thereof.

A first source-drain electrode 114 and a second source-drain electrode 115 can be disposed on the fourth insulating layer 104. The fourth insulating layer 104 and the third insulating layer 103 can have contact holes to contact the first and second source-drain electrodes 114 and 115 at both ends of the active layer 112 and the corresponding areas can be removed.

The gate electrode 113 and the first and second source-drain electrodes 114 and 115 can each be formed as a single layer or multiple layers.

When the gate electrode 113 and the first and second source electrodes 114 and 115 are single layers, they can be formed of one selected from the group consisting of molybdenum (Mo), aluminum (Al), chromium (Cr), gold (Au), titanium (Ti), nickel (Ni), neodymium (Nd), or copper (Cu), or an alloy thereof. In addition, when the gate electrode 113 and the first and second source-drain electrodes 114 and 115 include multiple layers, they can include double layers of molybdenum/aluminum-neodymium, molybdenum/aluminum, titanium/aluminum, or copper/molytitanium. Alternatively, the gate electrode 113 and the first and second source-drain electrodes 114 and 115 can include triple layers of molybdenum/aluminum-neodymium/molybdenum, molybdenum/aluminum/molybdenum, titanium/aluminum/titanium, or molybdenum/copper/molybdenum.

However, the configuration of the gate electrode 113 and the first and second source-drain electrodes 114 and 115 is not limited thereto, and the gate electrode 113 and the first and second source-drain electrodes 114 and 115 can include multiple layers formed of one selected from the group consisting of molybdenum (Mo), aluminum (Al), chromium (Cr), gold (Au), titanium (Ti), nickel (Ni), neodymium (Nd), or copper (Cu), or an alloy thereof.

The first to fourth insulating layers 101, 102, 103 and 104 can each be formed as inorganic insulating layers. The inorganic insulating layer can be, for example, formed as at least one of a silicon oxide layer, a silicon nitride layer, or a silicon oxynitride layer.

A first planarization layer 105 and a second planarization layer 106 can be provided on the first to fourth insulating layers 101, 102, 103, and 104. The first planarization layer 105 can have a contact hole, and a connecting electrode 116 connected to the second source-drain electrode 115 can be provided in the contact hole. The second planarization layer 106 is disposed to cover the connecting electrode 116 and the first planarization layer 105. The first and second planarization layers 105 and 106 can each include an organic material. The organic material can include at least one material from an acrylic resin, a phenolic resin, a polyimide resin, an unsaturated polyester resin, a polyamide resin, a benzocyclobutene resin, a polyphenylene resin, or a polyphenylene sulfide resin.

The connecting electrode 116 can be provided as multiple layers formed of one selected from the group consisting of molybdenum (Mo), aluminum (Al), chromium (Cr), gold (Au), titanium (Ti), nickel (Ni), neodymium (Nd), or copper (Cu), or an alloy thereof. However, the embodiments of the present disclosure are not limited thereto. In some cases, the connecting electrode 116 can be omitted. When the connecting electrode 116 is omitted, one of the first and second source-drain electrodes 114 and 115 can be directly connected to the first electrode AND of the light emitting device ED.

The light emitting device ED is formed by laminating a first electrode AND, an intermediate layer EL, and a second electrode CAT.

The first electrode AND can act as an anode. The first electrode AND can pass through a second planarization layer 106 and a first planarization layer 105, and be connected to a thin film transistor TFT. The thin film transistor TFT may be the first transistor T1 or the second transistor T2 as mentioned above. In the illustrated example, a connecting electrode 116 is further provided between the first electrode AND and the thin film transistor TFT, and the thin film transistor TFT is connected to the connecting electrode 116 and the connecting electrode 116 is connected to the first electrode AND. However, the second source-drain electrode 115 of the thin film transistor TFT and the first electrode AND of the light emitting device ED can be directly connected without the connecting electrode 116.

The first electrode AND can include, for example, a metal material having high reflectivity. For example, the first electrode AND can be formed as a multilayer structure such as a stacked structure of aluminum (Al) and titanium (Ti) (Ti/Al/Ti), a stacked structure of aluminum (Al) and ITO (ITO/Al/ITO), an APC (Ag/Pd/Cu) alloy, a stacked structure of an APC alloy and ITO (ITO/APC/ITO), a stacked structure of silver (Ag) and molybdenum/titanium alloy (Ag/MoTi), or can include a single layer structure formed of one material selected from silver (Ag), aluminum (Al), molybdenum (Mo), gold (Au), magnesium (Mg), calcium (Ca), and barium (Ba), or an alloy of two or more. The first electrode AND can be referred to as a “reflective electrode”.

An intermediate layer EL is provided on the first electrode AND. The intermediate layer EL can include a hole transport common layer CML1 such as a hole injection layer HIL and a hole transport layer HTL, a color optional layer RFL, GFL, BFL or AFL of each subpixel, and an electron-related electron transport common layer CML2 such as an electron transport layer ETL and an electron injection layer EIL.

The color optional layers RFL, GFL, BFL, and AFL of the respective subpixels can have different thicknesses, as shown in FIG. 2. The red optional layer RFL can be thicker than the auxiliary optional layer AFL and other color optional layers GFL and BFL.

As shown in FIG. 2, a red subpixel RSP is provided with a red optional layer RFL in which a red hole transport auxiliary layer RPL including a laminate of a second hole transport auxiliary layer PL2 and a third hole transport auxiliary layer PL3, and a red light emitting layer REML are laminated. The green subpixel GSP is provided with a green optional layer GFL in which a second hole transport auxiliary layer PL2 and a green emitting layer GEML are laminated. The blue subpixel BSP is provided with a blue optional layer BFL in which a first hole transport auxiliary layer PL1 and a blue emitting layer BEML are laminated. The auxiliary subpixel ASP is provided with an auxiliary optional layer AFL in which a third hole transport auxiliary layer PL3 and a red light emitting layer REML are laminated.

The intermediate layer EL can include a plurality of stacks in at least one subpixel RSP, GSP, BSP, or ASP. Here, the plurality of stacks can be distinguished from each other by charge generation layers and each stack can include at least one light emitting layer and at least one common layer. For example, the charge generation layer can include an n-type charge generation layer and a p-type charge generation layer.

The edge of the first electrode AND of each subpixel RSP, GSP, or BSP can overlap the bank 150. The area of the first electrode AND exposed from the bank 150 can be a light emitting portion REM, GEM, or BEM. The bank 150 opens the light emitting portion REM, GEM, or BEM of each subpixel RSP, GSP, or BSP. The bank 150 can include an organic or inorganic insulating material. The bank 150 can include a black material to effectively prevent reflection of external light and prevent color mixing between adjacent subpixels.

When voltage is applied to the first electrode AND and the second electrode CAT, holes and electrons move to the organic light emitting layer through the hole injection layer and the hole transport layer, and the electron injection layer and the electron transport layer, respectively, and in the organic light emitting layer, holes and electrons combine with each other to form excitons, and the excitons fall from an excited state to a ground state, thereby resulting in light emission.

Two or more layers, or at least one layer included in the intermediate layer EL: REL, GEL, or BEL can be provided in common throughout the entire display area AA.

The second electrode CAT can be a common layer that is commonly disposed in the subpixels SP and applies the same voltage. For this purpose, the second electrode CAT can extend from the display area AA to a part of the non-display area NA.

The second electrode CAT can be a light-transmitting electrode. The second electrode CAT can include a transparent metal material (TCO, transparent conductive material) such as ITO (indium tin oxide) or IZO (indium zinc oxide) that can transmit light, or a semi-transmissive metal material (semi-transmissive conductive material) such as magnesium (Mg), silver (Ag), or an alloy of magnesium (Mg) and silver (Ag). When the second electrode CAT includes a semi-transmissive metal material, the light emission efficiency can be increased by the microcavity effect. When the second electrode CAT includes a semi-transmissive metal material, the thickness thereof can be small enough to transmit light.

The first electrode AND can include a reflective electrode to prevent light generated in the intermediate layer EL from being transmitted to the light-shielding component below the first electrode AND. Light generated in the intermediate layer EL resonates between the second electrode CAT and the first electrode AND, and is ultimately emitted upward through the second electrode CAT. Since the first electrode AND includes a reflective component, although the first electrode AND overlaps the wiring and the thin film transistor TFT, the light emitted from the light emitting device ED can be recognized in the light emitting portion REM, GEM, or BEM without being affected by the arrangement thereof.

The light emitting display device of the embodiments of the present disclosure exhibits a top-emission method in which light is emitted upward. In this case, the first electrode AND includes a reflective electrode, and the light generated from the intermediate layer EL is reflected and re-reflected between the first electrode AND and the second electrode CAT, resonates, and is finally emitted toward the second electrode CAT.

A capping layer can be further provided on the second electrode CAT to increase emission efficiency and protect the light emitting device ED. The capping layer can be provided together in the deposition process of the light emitting device ED.

An encapsulation layer 140 protecting the light emitting device ED can be further provided on the light emitting device ED. When the capping layer is disposed on the light emitting device ED, the encapsulation layer 140 is disposed on the capping layer.

The encapsulation layer 140 can be a single layer or multiple layers. When the encapsulation layer 140 is provided as multiple layers, it can be formed by laminating at least one inorganic encapsulation layer and at least one organic encapsulation layer. The inorganic encapsulation layer can prevent moisture penetration and the organic encapsulation layer can cover particles and flatten the surface. The organic encapsulation layer can be located inside the inorganic encapsulation layer on a plane. In this case, the inorganic encapsulation layer can prevent moisture penetration to the side.

An anti-reflective layer 180 including a light-shielding layer 170 and a color filter RCF, GCF, or BCF can be provided on the encapsulation layer 140. The anti-reflective layer 180 functions to prevent external light reflection instead of a polarizing plate.

The light-shielding layer 170 of the anti-reflective layer 180 is located in an area overlapping with the bank 150.

The color filter of the anti-reflective layer 180 includes a red color filter RCF overlapping the red light emitting portion REM1 and the color-adjusting light emitting portion REM2, a green color filter GCF overlapping the green light emitting portion GEM, and a blue color filter BCF overlapping the blue light emitting portion BEM.

The red color filter RCF is also provided on the color-adjusting light emitting portion REM2. The color-adjusting light emitting portion REM2 is driven along with the blue light emitting portion BEM to correct the blue color tone in the red direction. When the color-adjusting light emitting device AED provided in the color-adjusting light emitting portion REM2 is turned on, the red light emitted from the color-adjusting light emitting device AED passes through the red color filter RCF and is emitted.

When each light emitting portion REM1, GEM, BEM, REM2 is turned off, the anti-reflective layer 180 absorbs the light coming from the top in the anti-reflective layer 180 including the light-shielding layer 170 and the color filter RCF, GCF, or BCF, thereby preventing external light from being reflected by the first and second electrodes AND and CAT of the light emitting device ED. The light-shielding layer 170 is disposed between the light emitting portions REM1, GEM, BEM, REM2, and absorbs the light of the visible light wavelength range emitted into the disposed area. The red color filter RCF absorbs light of wavelengths other than red light, the green color filter GCF absorbs light of wavelengths other than green light, and the blue color filter BCF absorbs light of wavelengths other than blue light.

The light emitting display device according to the embodiment of the present disclosure can further include a color-adjusting light emitting portion REM2 including a red color filter RCF to enhance the red reflection visibility in the off state.

A protective layer 190 can further be provided on the anti-reflective layer 180. In some cases, the protective layer 190 can include a touch sensor. In some cases, the anti-reflective layer 180 can be disposed on the touch sensor. The touch sensor can include a touch buffer layer, a bridge layer, a touch insulation layer, a touch sensor layer, and a touch protection layer.

Hereinafter, the reason why the light emitting display device of the present disclosure includes both a red light emitting portion and a color-adjusting light emitting portion will be described.

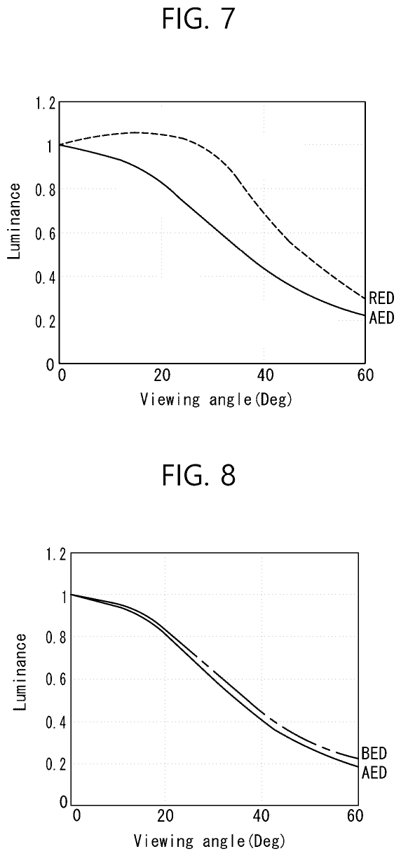

FIG. 6 is a graph showing the luminance depending on change in viewing angle when the red light emitting device and the blue light emitting device are driven. FIG. 7 is a graph showing the luminance depending on change in viewing angle when the red light emitting device and the color-adjusting light emitting device are driven. FIG. 8 is a graph showing the luminance depending on change in viewing angle when the blue light emitting device and the color-adjusting light emitting device are driven.

The optical distance between the first and second electrodes AND and CAT is set such that the red light emitting device RED provided in the red light emitting portion emits red light with optimal microcavity characteristics. In this case, as shown in FIG. 6, the red light emitting device RED has high luminance that is 0.7 times or more of the frontal luminance when observed at a viewing angle of about 40° from the front. In addition, the red light emitting device RED has luminance that is about 0.5 times that of the frontal luminance at a viewing angle of about 50°.

On the other hand, the blue light emitting device BED provided in the blue light emitting portion has 0.5 times the luminance of the front luminance when observed at a viewing angle of about 35° from the front, and the luminance halving degree is observed quickly upon a small viewing angle change compared to the front.

For example, as shown in FIG. 6, the blue light emitting device BED differs from the red light emitting device RED in terms of the viewing angle change.

Therefore, when the color correction of the blue light emitting device BED is adjusted by driving the red light emitting device RED, the color balance deteriorates when the viewing angle changes, and a specific color is prominent. For example, when the blue light emitting device BED is driven, the red light emitting device RED is driven at a low luminance to provide color correction, the elements are observed at a different viewing angle, and the problem in which red is more visible when blue is driven can occur.

The light emitting display device according to the embodiment of the present disclosure has a configuration in which a color-adjusting light emitting portion REM2 driven along for color correction of the blue light emitting device BED includes a color-adjusting light emitting device AED which has a similar viewing angle vs. luminance change as the blue light emitting device BED, as shown in FIGS. 7 and 8, so that the color balance of red and blue is maintained at a change in viewing angle. Accordingly, when the blue light emitting device BED and the color-adjusting light emitting device AED are driven simultaneously, deep blue is compensated into blue even upon a change in viewing angle, so that a wavelength-compensated blue color tone can be obtained. When the light emitting display device including the color-adjusting light emitting device AED and the blue light emitting device BED is observed at different viewing angles from the front, it is possible to prevent the phenomenon in which a specific color tone is prominent and maintain color balance.

Meanwhile, as shown in FIG. 7, the red light emitting device RED and the color-adjusting light emitting device AED have different optical distances and thus the viewing angle vs. luminance characteristic change rates are different. In addition, the change rate of the viewing angle vs. luminance characteristic of the color-adjusting light emitting device AED is similar to that of the blue light emitting device BED, as shown in FIG. 8.

A method of driving the light emitting display device according to an embodiment of the present disclosure will now be described.

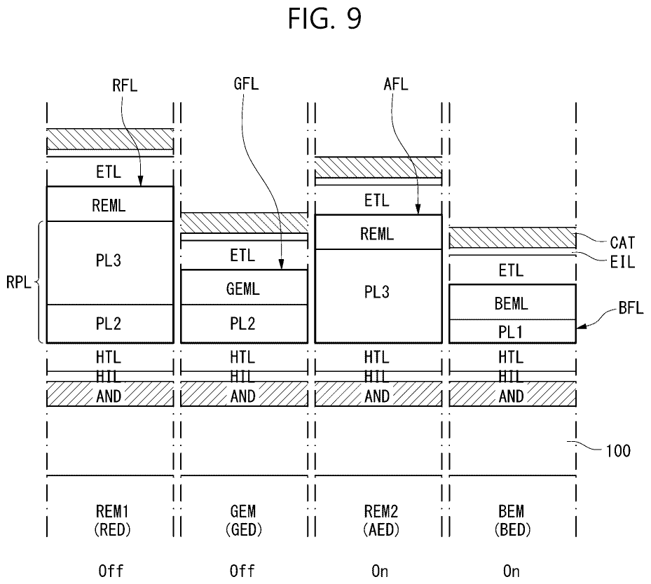

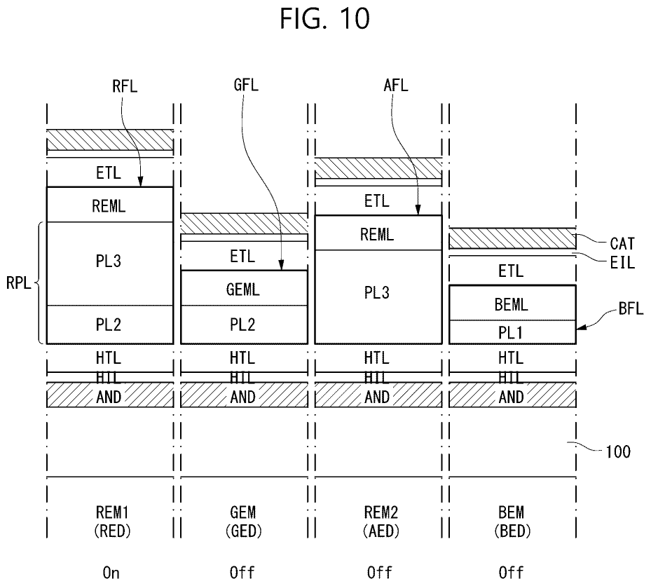

FIG. 9 illustrates an on/off state of light emitting portions in the light emitting display device of the present disclosure when blue is driven.

As shown in FIG. 9, the light emitting display device of the present disclosure turns on and drives the blue light emitting device BED of the blue light emitting portion BEM and the color-adjusting light emitting device AED of the color-adjusting light emitting portion REM2 together when blue is driven.

The driving of the blue light emitting device BED and the color-adjusting light emitting device AED is performed by generating a differential voltage between the first electrode AND and the second electrode CAT. For example, a common voltage such as a ground voltage can be applied to the second electrode CAT and a driving voltage can be applied to the first electrode AND through a thin film transistor TFT.

Here, the color-adjusting light emitting device AED is driven to correct blue and provides low luminance, and the driving voltage of the color-adjusting light emitting device AED can be lower than the driving voltage of the blue light emitting device BED.

In some cases, the first electrode AND of the color-adjusting light emitting device AED is connected to the first electrode AND of the blue light emitting device BED so that the color-adjusting light emitting device AED and the blue light emitting device BED can be turned on and driven simultaneously.

When blue is driven, the red light emitting device RED in the red light emitting portion REM1 and the green light emitting device GED in the green light emitting portion GEM are turned off.

FIG. 10 illustrates the states in which the light emitting portions are turned on/off when red is driven in the light emitting display device of the present disclosure.

As shown in FIG. 10, when red is driven, the red light emitting device RED in the red light emitting portion REM1 is turned on and the remaining green light emitting device GED in the green light emitting portion GEM, the color-adjusting light emitting device AED in the color-adjusting light emitting portion REM2, and the blue light emitting device BED in the blue light emitting portion BEM are turned off.

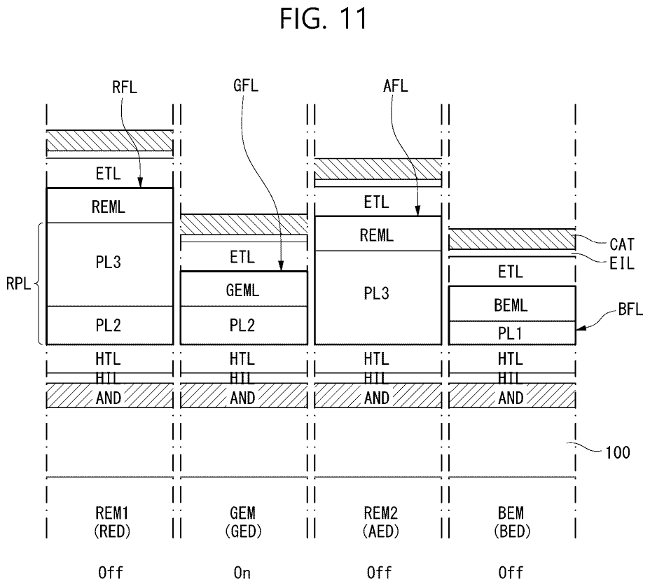

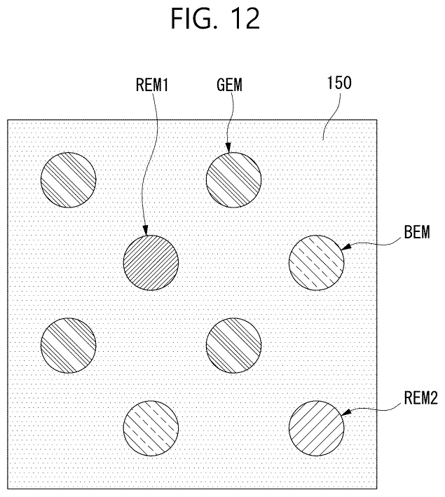

FIG. 11 shows the on/off states of the light emitting portions when the green is driven in the light emitting display device according to the disclosure.

As shown in FIG. 11, when green is driven, the green light emitting device GED in the green light emitting portion GEM is turned on, and the red light emitting device RED in the remaining red light emitting portion REM1, the color-adjusting light emitting device AED of the color-adjusting light emitting portion REM2, and the blue light emitting device BED in the blue light emitting portion BEM are turned off.

When white is driven in the light emitting display device of the present disclosure, the red light emitting device RED of the red light emitting portion REM1, the green light emitting device GED of the green light emitting portion GEM, and the blue light emitting device BED of the blue light emitting portion BEM are turned on. In this case, the color-adjusting light emitting device AED of the color-adjusting light emitting portion REM2 is turned off.

In some cases, the color-adjusting light emitting portion REM2 can be optionally turned on to prevent deviation of specific color tones due to changes in viewing angle when white is expressed.

A light emitting display device according to another embodiment of the present disclosure will be described.

FIG. 12 is a plan view illustrating a light emitting display device according to another embodiment of the present disclosure.

As shown in FIG. 12, in the light emitting display device according to another embodiment of the present disclosure, a red light emitting portion REM1, a blue light emitting portion BEM, a green light emitting portion GEM, and a color-adjusting light emitting portion REM2 are designed to have identical sizes. The opening areas of the bank 150 are provided to be spaced apart from each other, and different opening areas are set as a red light emitting portion REM1, a blue light emitting portion BEM, a green light emitting portion GEM, and a color-adjusting light emitting portion REM2.

Referring to FIG. 3, in a light emitting display device according to another embodiment of the present disclosure, a color-adjusting light emitting portion REM2 is disposed on a substrate 100 along with a red light emitting portion REM1 overlapping a red color filter RCF. For example, the configuration capable of providing a red reflection on the substrate 100 is provided with a greater proportion than the blue light emitting portion BEM or the green light emitting portion GEM. Therefore, the initial cyan-biased color tone can be corrected to normal black having no color deviation by increasing the reflection luminance of red, which is color complementary to cyan, in the initial state compared to blue or green.

As such, when this is applied to the structure of FIG. 12, the sizes of the light emitting portions REM1, BEM, GEM, and REM2 can be adjusted to be uniform and thus change in lifespan depending on color due to the difference in the size of the light emitting portions can be prevented.

A light emitting display device and a method of driving/operating the same according to various aspects of the present disclosure can be described as follows.

A light emitting display device according to one embodiment of the present disclosure can comprise a substrate, a bank on the substrate, the bank to expose a red light emitting portion, a green light emitting portion, a blue light emitting portion, and a color-adjusting light emitting portion spaced apart from each other, a red light emitting device at the red light emitting portion, a green light emitting device at the green light emitting portion, a blue light emitting device at the blue light emitting portion, and a color-adjusting light emitting device at the color-adjusting light emitting portion, an encapsulation layer covering the red light emitting device, the green light emitting device, the blue light emitting device, and the color-adjusting light emitting device and an anti-reflective layer on the encapsulation layer, the anti-reflective layer comprising a color filter overlapping the red light emitting portion, the green light emitting portion, the blue light emitting portion, and the color-adjusting light emitting portion.

In a light emitting display device according to one embodiment of the present disclosure, the color-adjusting light emitting device comprises a red light emitting layer, and an optical distance of the color-adjusting light emitting device is shorter than an optical distance of the red light emitting device.

In a light emitting display device according to one embodiment of the present disclosure, each of the red light emitting device, the green light emitting device, the blue light emitting device, and the color-adjusting light emitting device can comprise a first electrode and a second electrode facing each other and a first common layer and a second common layer between the first electrode and the second electrode.

The blue light emitting device can comprise a first hole transport auxiliary layer having a first thickness and a blue light emitting layer between the first common layer and the second common layer. The green light emitting device can comprise a second hole transport auxiliary layer having a second thickness and a green light emitting layer between the first common layer and the second common layer. The color-adjusting light emitting device can comprise a third hole transport auxiliary layer having a third thickness and a first red light emitting layer between the first common layer and the second common layer, and the red light emitting device can comprise a fourth hole transport auxiliary layer having a thickness that corresponds to a total thickness of the second thickness and the third thickness, and a second red light emitting layer between the first common layer and the second common layer.

In a light emitting display device according to one embodiment of the present disclosure, the first red light emitting layer and the second red light emitting layer can have the same thickness.

In a light emitting display device according to one embodiment of the present disclosure, the first red light emitting layer and the second red light emitting layer can comprise a same host material and a same dopant material.

In a light emitting display device according to one embodiment of the present disclosure, the color filter of the anti-reflective layer can comprise a red color filter overlapping the red light emitting portion and the color-adjusting light emitting portion, a green color filter overlapping the green light emitting portion, and a blue color filter overlapping the blue light emitting portion.

In a light emitting display device according to one embodiment of the present disclosure, the anti-reflective layer can further comprise a light-shielding layer overlapping the bank, and the light-shielding layer is disposed on the encapsulation layer.

In a light emitting display device according to one embodiment of the present disclosure, a thickness increases in an order of the first hole transport auxiliary layer, the second hole transport auxiliary layer, and the third hole transport auxiliary layer.

In a light emitting display device according to one embodiment of the present disclosure, the color-adjusting light emitting device can be turned on along with the blue light emitting device.

In a light emitting display device according to one embodiment of the present disclosure, the red light emitting portion can be larger than the green light emitting portion or the blue light emitting portion.

In a light emitting display device according to one embodiment of the present disclosure, a size of the color-adjusting light emitting portion can be smaller than or equal to a size of the red light emitting portion.

In a light emitting display device according to one embodiment of the present disclosure, an arrangement density of the color-adjusting light emitting portion on the substrate can be equal to or less than an arrangement density of the red light emitting portion.

In a light emitting display device according to one embodiment of the present disclosure, an arrangement density of the color-adjusting light emitting portion on the substrate can be equal to or less than an arrangement density of the blue light emitting portion.

In a light emitting display device according to one embodiment of the present disclosure, a size of the color-adjusting light emitting portion can be equal to a size of the blue light emitting portion.

In a light emitting display device according to one embodiment of the present disclosure, the bank can comprise a black material.

A method of driving a light emitting display device according to one embodiment of the present disclosure can comprise a red light emitting portion, a green light emitting portion, a blue light emitting portion, and a color-adjusting light emitting portion spaced apart from each other on a substrate. The red light emitting portion can be driven alone when red is driven, and the green light emitting portion can be driven alone when green is driven. The blue light emitting portion and the color-adjusting light emitting portion can be driven together when blue is driven.

In a method of driving a light emitting display device according to one embodiment of the present disclosure, the color-adjusting light emitting portion and the red light emitting portion can comprise the same red light emitting layer between the first electrode and the second electrode.

A distance between the first electrode and the red light emitting layer at the color-adjusting light emitting portion can be shorter than a distance between the first electrode and the red light emitting layer at the red light emitting portion.

In a method of driving a light emitting display device according to one embodiment of the present disclosure, the green light emitting portion can comprise a green light emitting layer between the first electrode and the second electrode facing each other. The blue light emitting portion can comprise a blue light emitting layer between the first electrode and the second electrode.

A distance between the first electrode and the green light emitting layer at the green light emitting portion is shorter than a distance between the first electrode and the red light emitting layer at the color-adjusting light emitting portion.

In a method of driving a light emitting display device according to one embodiment of the present disclosure, each of the red light emitting device, the green light emitting device, the blue light emitting device, and the color-adjusting light emitting device can comprise a first electrode and a second electrode facing each other and a first common layer and a second common layer between the first electrode and the second electrode. The blue light emitting device can comprise a first hole transport auxiliary layer having a first thickness and a blue light emitting layer between the first common layer and the second common layer, the green light emitting device can comprise a second hole transport auxiliary layer having a second thickness and a green light emitting layer between the first common layer and the second common layer, the color-adjusting light emitting device can comprise a third hole transport auxiliary layer having a third thickness and a first red light emitting layer between the first common layer and the second common layer, and the red light emitting device can comprise a fourth hole transport auxiliary layer having a thickness that corresponds to a total thickness of the second thickness and the third thickness, and a second red light emitting layer between the first common layer and the second common layer.

In a method of driving a light emitting display device according to one embodiment of the present disclosure, the first red light emitting layer and the second red light emitting layer can have the same thickness.

In a method of driving a light emitting display device according to one embodiment of the present disclosure, when blue is driven, a driving voltage of the blue light emitting portion can be greater than a driving voltage of the color-adjusting light emitting portion.

The effects of the light emitting display device and the method of driving the same according to the present disclosure are as follows.

The light emitting display device according to one embodiment of the present disclosure further includes a color-adjusting light emitting portion including a red light emitting layer in addition to the red, green, and blue light emitting portions, and the color-adjusting light emitting portion can be driven along with the blue light emitting portion to correct the color tone of blue and improve visibility.

When only the red, green, and blue light emitting portions are provided, the color-adjusting light emitting portion including a red color filter can be further provided so that color is compensated into red which is color complementary to cyan in the initial state to provide normal black.

In addition, the color-adjusting light emitting portion can adjust the optical distance compared to the red light emitting portion to provide a luminance variability for a viewing angle similar to that of blue, and can prevent the color balance from being broken upon change in viewing angle when blue is driven.

The light emitting display device according to the embodiments of the present disclosure further includes a color-adjusting light emitting portion by providing a hole transport auxiliary layer included as a component of an adjacent light emitting portion to prevent a phenomenon in which a specific color is perceived in an initial state or during operation, provide high color reproducibility, achieve process optimization and provide sustainable advantages, thereby achieving ESG (environmental/social/governance) goals.

It will be apparent to those skilled in the art that various modifications and variations can be made in the present disclosure without departing from the spirit or scope of the inventions. Thus, it is intended that the present disclosure covers the modifications and variations of this invention provided they come within the scope of the appended claims and their equivalents.

What is claimed is:

1. A light emitting display device comprising:
a bank on a substrate and exposing a red light emitting portion, a green light emitting portion, a blue light emitting portion, and a color-adjusting light emitting portion that are spaced apart from each other;
a red light emitting device at the red light emitting portion, a green light emitting device at the green light emitting portion, a blue light emitting device at the blue light emitting portion, and a color-adjusting light emitting device at the color-adjusting light emitting portion;
an encapsulation layer covering the red light emitting device, the green light emitting device, the blue light emitting device, and the color-adjusting light emitting device; and
an anti-reflective layer on the encapsulation layer, the anti-reflective layer comprising a color filter overlapping the red light emitting portion, the green light emitting portion, the blue light emitting portion, and the color-adjusting light emitting portion.

2. The light emitting display device according to claim 1, wherein the color-adjusting light emitting device comprises a red light emitting layer, and
wherein an optical distance of the color-adjusting light emitting device is shorter than an optical distance of the red light emitting device.

3. The light emitting display device according to claim 1, wherein each of the red light emitting device, the green light emitting device, the blue light emitting device, and the color-adjusting light emitting device comprises:
a first electrode and a second electrode facing each other; and
a first common layer and a second common layer between the first electrode and the second electrode,
wherein the blue light emitting device comprises a first hole transport auxiliary layer having a first thickness, and a blue light emitting layer between the first common layer and the second common layer,
wherein the green light emitting device comprises a second hole transport auxiliary layer having a second thickness, and a green light emitting layer between the first common layer and the second common layer,
wherein the color-adjusting light emitting device comprises a third hole transport auxiliary layer having a third thickness, and a first red light emitting layer between the first common layer and the second common layer, and
wherein the red light emitting device comprises a fourth hole transport auxiliary layer having a thickness that corresponds to a combined total thickness of the second thickness and the third thickness, and a second red light emitting layer between the first common layer and the second common layer.

4. The light emitting display device according to claim 3, wherein the first red light emitting layer and the second red light emitting layer have a same thickness.

5. The light emitting display device according to claim 3, wherein the first red light emitting layer and the second red light emitting layer comprise a same host material and a same dopant material.

6. The light emitting display device according to claim 1, wherein the color filter of the anti-reflective layer comprises:
a red color filter overlapping the red light emitting portion and the color-adjusting light emitting portion;
a green color filter overlapping the green light emitting portion; and
a blue color filter overlapping the blue light emitting portion.

7. The light emitting display device according to claim 1, wherein the anti-reflective layer further comprises a light-shielding layer overlapping the bank, and
wherein the light-shielding layer is disposed on the encapsulation layer.

8. The light emitting display device according to claim 3, wherein a thickness increases in an order of the first hole transport auxiliary layer, the second hole transport auxiliary layer, and the third hole transport auxiliary layer.

9. The light emitting display device according to claim 1, wherein the color-adjusting light emitting device is turned on along with the blue light emitting device.

10. The light emitting display device according to claim 1, wherein the red light emitting portion is larger in size than the green light emitting portion or the blue light emitting portion.

11. The light emitting display device according to claim 1, wherein a size of the color-adjusting light emitting portion is smaller than or equal to a size of the red light emitting portion.

12. The light emitting display device according to claim 11, wherein an arrangement density of the color-adjusting light emitting portion on the substrate is equal to or less than an arrangement density of the red light emitting portion.

13. The light emitting display device according to claim 1, wherein an arrangement density of the color-adjusting light emitting portion on the substrate is equal to or less than an arrangement density of the blue light emitting portion.

14. The light emitting display device according to claim 1, wherein a size of the color-adjusting light emitting portion is equal to a size of the blue light emitting portion.

15. The light emitting display device according to claim 1, wherein the bank comprises a black material.

16. A method of driving a light emitting display device including a red light emitting portion, a green light emitting portion, a blue light emitting portion, and a color-adjusting light emitting portion that are disposed spaced apart from each other on a substrate, the method comprising:
driving the red light emitting portion alone when red is driven, and driving the green light emitting portion alone when green is driven; and
driving the blue light emitting portion and the color-adjusting light emitting portion together when blue is driven.

17. The method according to claim 16, wherein each of the red light emitting portion, the green light emitting portion, the blue light emitting portion, and the color-adjusting light emitting portion comprises a first electrode and a second electrode facing each other,
wherein the color-adjusting light emitting portion and the red light emitting portion comprise a same red light emitting layer between the first electrode and the second electrode, and
wherein a distance between the first electrode and the red light emitting layer at the color-adjusting light emitting portion is shorter than a distance between the first electrode and the red light emitting layer at the red light emitting portion.

18. The method according to claim 17, wherein the green light emitting portion comprises a green light emitting layer between the first electrode and the second electrode,
wherein the blue light emitting portion comprises a blue light emitting layer between the first electrode and the second electrode, and
wherein a distance between the first electrode and the green light emitting layer at the green light emitting portion is shorter than a distance between the first electrode and the red light emitting layer at the color-adjusting light emitting portion.

19. The method according to claim 16, wherein each of the red light emitting portion, the green light emitting portion, the blue light emitting portion, and the color-adjusting light emitting portion comprises:
a first electrode and a second electrode facing each other; and
a first common layer and a second common layer between the first electrode and the second electrode,
wherein the blue light emitting portion comprises a first hole transport auxiliary layer having a first thickness, and a blue light emitting layer between the first common layer and the second common layer,
wherein the green light emitting portion comprises a second hole transport auxiliary layer having a second thickness, and a green light emitting layer between the first common layer and the second common layer,
wherein the color-adjusting light emitting portion comprises a third hole transport auxiliary layer having a third thickness and a first red light emitting layer between the first common layer and the second common layer, and
wherein the red light emitting portion comprises a fourth hole transport auxiliary layer having a thickness that corresponds to a combined total thickness of the second thickness and the third thickness, and a second red light emitting layer between the first common layer and the second common layer.

20. The method according to claim 19, wherein the first red light emitting layer and the second red light emitting layer have a same thickness.

21. The method according to claim 16, wherein, when blue is driven, a driving voltage of the blue light emitting portion is greater than a driving voltage of the color-adjusting light emitting portion.
